(19) United States
(12) Patent Application Publication
(10) Pub. No.: US 2008/0314438 A1
(43) Pub. Date: Dec. 25, 2008

(54) INTEGRATED CONCENTRATOR PHOTOVOLTAICS AND WATER HEATER

(76) Inventors: Alan Anthuan Tran, San Jose, CA (US); Bao Tran, San Jose, CA (US)

Correspondence Address: Bao Q. Tran, 6768 Meadow Vista Court, San Jose, CA, 95135, US

(21) Appl. No.: 11/765,991

(22) Filed: Jun. 20, 2007

(51) Int. Cl. H01L 31/058

(52) U.S. Cl. 136/248

(57) ABSTRACT

An energy device includes a solar concentrator that concentrates at least 20 suns on a predetermined spot; a solar cell positioned on the predetermined spot to receive concentrated solar energy from the solar concentrator; and a water heater pipe thermally coupled to the solar cell to remove heat from the solar cell.

### BACKGROUND

Worldwide energy consumption is expected to double in the next 20 years, and negative effects on the climate from classic fossil-fuel based power plants are accelerating. The current climate means that it's now critical for clean-energy technologies such as solar photovoltaic (PV) to deliver lower-cost energy and to rapidly scale up to terawatt capacity.

Traditionally, the solar energy industry has relied on silicon to generate power. But silicon is expensive. Further, the solar industry faces a silicon feedstock shortage, while at the same time module production capacity is expected to double, driving up costs through increased competition for material. Power grids are struggling to keep up with peak demand loads, as evidenced by recent blackouts in the U.S., as well as China, Europe and other industrialized nations.

### BRIEF DESCRIPTION OF THE DRAWINGS

FIG. 1 shows a cross-sectional view of an array of concentrator photovoltaics (CPV) cells and a water heater.

FIG. 2 shows a bottom view of the system of FIG. 1.

FIG. 3 shows a cross sectional view of an exemplary high efficiency PV cell.

FIG. 4 shows another embodiment where each solar element has two solar cells.

FIG. 5 shows another embodiment where Fresnel lenses concentrate solar energy to the solar cell.

FIG. 6 shows another embodiment where multiple levels of Fresnel lenses are used to concentrate light onto a dense array of solar cells.

FIG. 7 shows one or more lenses placed in the path of the concentrated light to provide focus.

FIG. 8 shows another embodiment where glass or plastic lenses are placed above the cells.

FIG. 9 shows a honey bee eye concentrator solar cell arrangement.

FIG. 10 and FIG. 11A-11B show various exemplary solar-thermoelectric embodiments.

FIG. 12 shows an exemplary solar-Stirling engine embodiment.

### SUMMARY

An energy device includes a solar concentrator that concentrates at least 20 suns on a predetermined spot; a solar cell positioned on the predetermined spot to receive concentrated solar energy from the solar concentrator; and a water heater pipe thermally coupled to the solar cell to remove heat from the solar cell.

Implementations of the energy device may include one or more of the following. Te solar concentrator heats the water heater pipe. The solar concentrator can be a mirror, a lens, or a mirror-lens combination. An inverter can generate AC power to supply to an electricity grid and a water pump to distribute heated water to a building. An alternating current (AC) voltage booster can receive the input voltage from the solar cell and a DC regulator coupled to the AC voltage booster to charge the battery. The AC voltage booster can be a step-up transformer or a pulse-width-modulation (PWM) voltage booster. The solar concentrator can have a first curved reflector adapted to reflect light to a second curved reflector and wherein the second curved reflector concentrates sun light on the solar cell. One or more capacitors can store a stepped-up voltage before applying the stepped-up voltage to a battery. A frequency shifter can change the frequency of the AC voltage to avoid radio frequency interference. A DC regulator can be connected between the voltage booster and the battery.

In another aspect, a method for providing renewable energy includes concentrating sun light onto a photovoltaic (PV) cell; receiving a direct current (DC) input voltage from the cell; converting the direct current input voltage into an alternating current (AC) voltage; stepping-up the AC input voltage; and applying the stepped-up voltage to an energy storage device.

Implementations of the method may include one or more of the following. The input voltage can be stepped up using a transformer or using pulse-width-modulation (PWM). AC power can be generated from the battery. The PV cell can be cooled and the energy can be used to heat up a water heater pipe. The stepping up the input voltage can proximally double the input voltage. The stepped-up energy can be stored in one or more capacitors or supercapacitors before applying the stepped-up voltage to the battery. The supercapacitors can use nano-particles to provide high storage capacity.

Advantages of the system may include one or more of the following. Using optical lenses and/or mirrors, the system concentrates the sunlight onto a very small, highly efficient Multi-Junction solar cell. For example, under 500-sun concentration, 1 cm² of solar cell area produces the same electricity as 500 cm² would without concentration. This is particularly significant when considering the inherent efficiency advantage of the Multi-Junction technology over Silicon solar cells. The use of concentration, therefore, allows substitution of cost-effective materials such as lenses and mirrors for the more costly semiconductor PV cell material. High efficiency Multi-Junction cells have a significant advantage over conventional silicon cells in concentrator systems because fewer solar cells are required to achieve the same power output. The system provides a wide acceptance angle (+/−1°), which enhances manufacturability, and a thin panel profile, which reduces weight, installation complexity, and cost. The additional power generators such as the Peltier Junction cells or the Stirling engine captures wasted heat and boosts energy efficiency while lowering cost. Further, the system captures the resulting heat on the cells to one or more cooling pipes, which in turn provides solar heated water or alternatively purified water for human consumption. Through advances in high volume manufacturing and increased solar cell efficiency to greater than 40% efficiency, the system reduces the cost of generating electricity from solar energy.

### DESCRIPTION

FIG. 1 shows a cross-sectional view of an array of CPV elements 1 and a water heater 30. In the embodiment of FIG. 1, a first reflector 10 reflects sun light 12 to a second reflector 14. The second reflector 14 can be concave (Gregorian configuration) or convex (Cassegrain configuration). The second reflector 14 is mounted to a front window (not shown) for protection from the elements. The position of the solar cell 20 in FIG. 1 is for illustration purpose, and the solar cell is mounted below the first reflector 10 as is known to one skilled in the art. In general, the reflectors 10 and 14 focus the sun's energy into an optical rod, which guides the sunlight onto a solar cell 20 at the bottom of the rod. The high-efficiency cells are mounted to a heat spreader 22, which in turn is coupled to a water heater tube 30 that removes heat from the solar cell 20 and the heat spreader 22. High cell temperature not only reduces the cell performance but also reduces the reliability of the system, and so the water heater tube 30 removes the heat from the cells. The output of the heater tube 30 is heated water for subsequent use. The heater tube 30 can also be directly attached to the solar cell 20 without the heat spreader 22 in one embodiment.

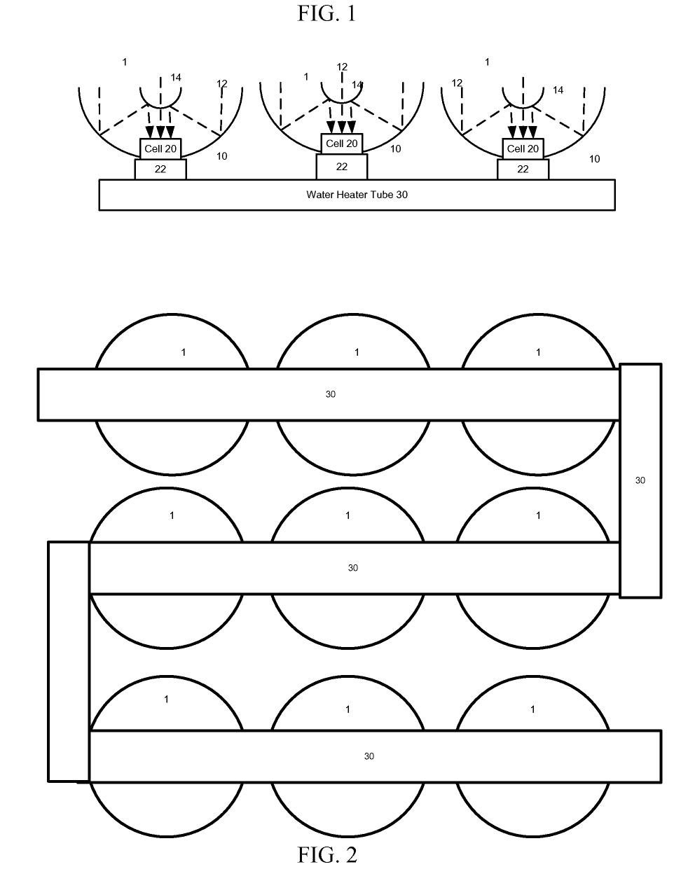

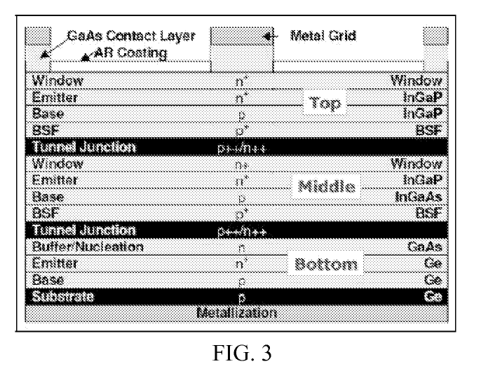

FIG. 2 shows a bottom view of the integrated CPV and water heater with tube 30 that removes heat from solar cell 20 as heated water for subsequent heated water consumption. In one embodiment, cold water, which normally goes to the bottom of the conventional water heater, is detoured to the heater first. An electric circulating pump moves heat from a collector to the building's hot water storage tank. A differential controller turns the circulating pump on or off as required. There are two sensors, one at the outlet of the collectors, and the other at the bottom of the tank. They signal the controller to turn the pump on when the collector outlet is 20° F. (11° C.) warmer than the bottom of the tank. It shuts off when the temperature differential is reduced to 5° F. (2.8° C.). Solar preheated water then becomes the cold water input to the existing water heater.

In another embodiment, instead of providing heated water, the tube 30 is used as a solar still which operates using the basic principles of evaporation and condensation. The contaminated feed water goes into the still and the sun's rays penetrate a glass surface causing the water to heat up through the greenhouse effect and subsequently evaporate. When the water evaporates inside the still, it leaves all contaminants and microbes behind in the basin. The evaporated and now purified water condenses on the underside of the glass and runs into a collection trough and then into an enclosed container. In this process the salts and microbes that were in the original feed water are left behind. Additional water fed into the still flushes out concentrated waste from the basin to avoid excessive salt build-up from the evaporated salts. The solar still effectively eliminates all waterborne pathogens, salts, and heavy metals. Solar still technologies bring immediate benefits to users by alleviating health problems associated with water-borne diseases. For solar stills users, there is a also a sense of satisfaction in having their own trusted and easy to use water treatment plant on-site.

The solar cells and water heater are mounted on a mobile platform controlled by a pan/tilt unit (PTU). The system can vary its orientation from horizontal to sun-pointing or any other fixed direction at any given moment. The platform can adjust the incident sun-angle over the efficiency of the solar cells due to reflections and varying path-lengths on each semiconductor caused by changes in the angle of the incident light. Sun position is analytically determined knowing the geographical location and current date. One system uses a Directed Perception Model PTU-C46-70 pan/tilt unit based on stepper motors with a PTU controller which is operated using a standard RS/232 serial line of the main computer. The PTU has a freedom of 300° pan, 46° tilt (bottom) and 31° tilt (top).

The solar cell can be a multi-junction solar cell. In one embodiment, the solar cell is a quadruple junction solar cell or a quintuple junction solar cell such as those described in U.S. Pat. No. 7,122,733, the content of which is incorporated by reference.

In another embodiment, the solar cell is an advanced triple-junction (ATJ) solar cell. The triple-junction solar cell—or TJ solar cell—generates a significant amount of energy from a small cell. In one implementation, a 1-cm² cell can generate as much as 35 W of power and produce as much as 86.3 kWh of electricity during a typical year under a Phoenix, Ariz. sun. The triple-junction approach uses three cells stacked on top of each other, each cell of which is tuned to efficiently convert a different portion of the solar spectrum to electricity. As a result, the cell converts as much as 34% of sunlight to electricity, which is almost 40% higher than its nearest competitor. Second, the TJ solar cell is designed to be used under high concentrations of sunlight, several times higher than any other cell. At its highest rated concentration (1200 suns), the TJ solar cell produces three times the power of its nearest competitor.

In one implementation, ATJ solar cells manufactured by Emcore Photovoltaics are used. Each unit is comprised of several semiconductor layers, which are monolithically grown over Ge wafers. The solar cell has three main junctions that individually take advantage of a different section of the incident radiation spectrum. The first junction, which takes advantage of the UV light, is built from InGaP, and has the largest bandgap of three junctions. The medium junction is constructed of InGaP/InGaAs, and has medium sized bandgap, which makes up most of the visible light. Finally the bottom layer is germanium which receives photons not absorbed by the other layers, and consequently has the smallest bandgap. In another embodiment, the Ultra Triple Junction (UTJ) solar cells from Spectrolab can be used. More information on the UTJ solar cell is disclosed in U.S. Pat. Nos. 6,380,601, 6,150,603, and 6,255,580, the contents of which are incorporated by reference.

ATJ solar cells include several features that allow them to generate electricity with high conversion efficiencies. Among them, the use of window and back surface field (BSF) layers, which are high-bandgap layers that reduce recombination effects due to surface defects, shifting the electron-hole pair generation to places nearer the junction. Additionally, the InGaP top and InGaAs middle cells are lattice matched to the Ge substrate, therefore defects between layers are minimized. The n- and p-contact metallization is mostly comprised of Ag, with a thin Au layer to prevent oxidation. The antireflection coating (AR) is a broadband dual-layer TiOx/Al2O3 dielectric stack, whose spectral reflectivity characteristics are designed to minimize reflection in broad band of wavelengths. The InGaP/InGaAs/Ge advanced triple-junction (ATJ) solar cells are epitaxially grown in organo-metallic chemical vapor deposition (OMCVD) reactors on 140-μm uniformly thick germanium substrates. The solar cell structures are grown on 100-mm diameter (4 inch) Ge substrates with an average mass density of approximately 86 mg/cm2. Each wafer typically yields two large-area solar cells. The cell areas that are processed for production typically range from 26.6 to 32.4 cm2. The epi-wafers are processed into complete devices through automated robotic photolithography, metallization, chemical cleaning and etching, antireflection (AR) coating, dicing, and testing processes.

ATJ solar cells present a variable-efficiency characteristic which is dependent on the angle of incidence of the sunlight. Higher efficiencies are obtained when the sun is positioned normal to the solar cell. In one embodiment, the ATJ cell minimizes effects caused by an extension of the optical path lengths (OPLs) in the antireflection (AR) coatings and semiconductor layers. The OPL is kept constant in the AR coatings to improve the antireflection effectiveness for which the semiconductor layers widths were optimized (current-matching). In another embodiment, the ATJ cells have micro-pyramidal top surfaces that capture light from wider angles of incidence. In one embodiment, the solar cells are fabricated with microlens above the top layer. The micro lens can be formed with a viscosity-optimized UV-curable fluorinated acrylate polymer. Flexible control of the curvature of lens-tip is done through control of deposited volume and surface tension of the liquid polymer. In yet another embodiment, a tunable-focus microlens array uses polymer network liquid crystals (PNLCs). PNLCs are prepared by ultraviolet (UV) light exposure through a patterned photomask. The UV-curable monomer in each of the exposed spots forms an inhomogeneous centro-symmetrical polymer network that functions as a lens when a homogeneous electric field is applied to the cell. The focal length of the microlens is tunable with the applied voltage.

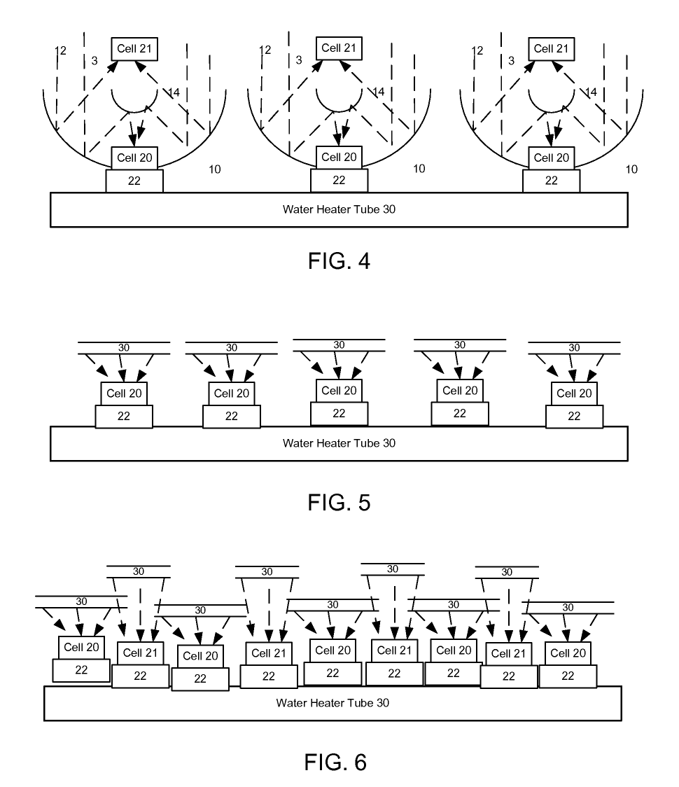

FIG. 4 shows another embodiment where each solar element 3 has two solar cells. Solar cell 20 is positioned in the same arrangement of FIG. 1, while a second solar cell 21 is positioned at a second focus point to receive solar energy in a different spectrum. In one embodiment, the solar cell 21 is an infrared solar cell and the second focus point is at the long-wavelength infrared focal point. The configuration of FIG. 4 is a Cassegrainian mirror configuration commonly used in telescopes, and the secondary mirror is a dichroic secondary that either transmits or reflects. The infrared solar cell can be a GaSb infrared cell, among others.

FIG. 5 shows another embodiment where fresnel lenses 30 are used to concentrate solar energy to the solar cell 20. The fresnel lenses can be made of glass, silicone or plastic, and can be hermetically sealed with the solar cell. In this embodiment, inexpensive flat, plastic Fresnel lenses as an intermediary between the sun and the cell. A typical Fresnel lens is made up of many small narrow concentric rings. Each ring can be considered as an individual small lens that bends the light path. The curvature in each ring is approximated by a flat surface so that each ring behaves like an individual wedge prism. These magnifying lenses focus and concentrate sunlight approximately 500 times onto a relatively small cell area and operate similarly to the glass magnifying lenses to burn things with. Through concentration, the required triple junction cell area needed for a given amount of electricity is reduced by an amount approximating its concentration ratio (500 times). In effect, a low cost plastic concentrator lens is being substituted for relatively expensive silicon. In one embodiment, a convex secondary lens can be positioned between the fresnel lens 30 and the solar cell 20 to provided better focusing capability. A short focal distance allows a compact and flat design, hermetically sealed with glass.

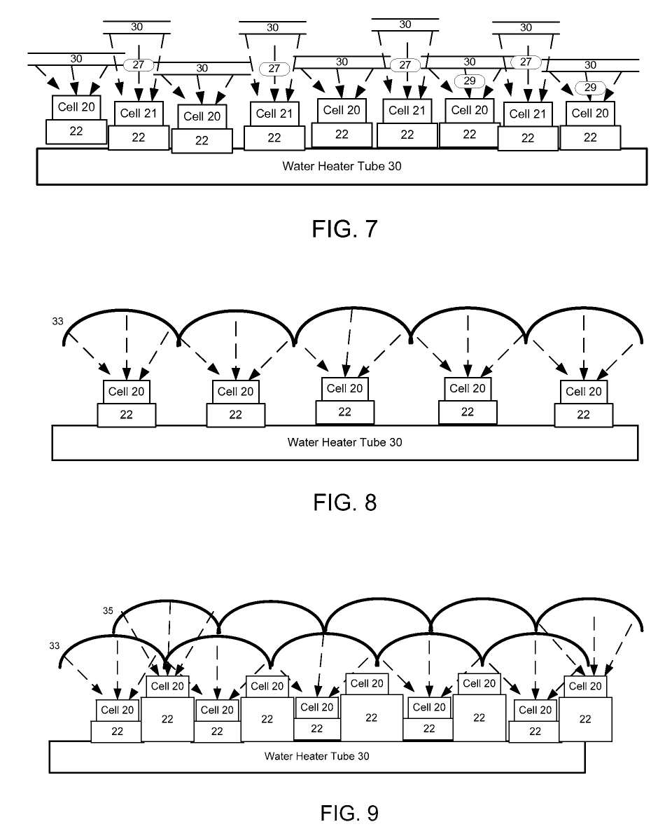

FIG. 6 shows yet another embodiment where multiple levels of fresnel lenses are used to concentrate light onto a dense array of solar cells. As shown therein, fresnel lenses 30 concentrate light onto cell 20 as is done in FIG. 5. An additional array of cells 21 are positioned between the cells 20 to provide a high density concentrated array of solar cells. The array of cells 21 receive concentrated solar light focused on by a second array of fresnel lenses 30 positioned above the cells 21. In one embodiment, the solar cells 21 are planar with the cells 20. In another embodiment, the solar cells 21 are positioned at a different height from the height of the cells 20 to allow for a predetermined focus depth. One or more lenses 27 or 29 can be placed in the path of the concentrated light to provide focus, as shown in FIG. 7. Cell 21 can be an infrared sensitive solar cell based on GaSb (among others) or a visible spectrum solar cell.

FIG. 8 shows another embodiment where an array of glass or plastic lens are placed above the cells 20 to focus and concentrate solar light onto the cells 20. This embodiment is inexpensive to make and can be mass manufactured quite inexpensively.

FIG. 9 shows a honey bee eye concentrated solar cell arrangement where cells 20 are positioned in a variety of angles to capture as much sunlight as possible, regardless of how accurately the array is aimed at the sun. Above the cell 20 are lenses 33 and 35 which are positioned at different positions to ensure that the target cells are properly focused. This embodiment is biologically inspired by the eyes of the bees which can have up to 9000 cells.

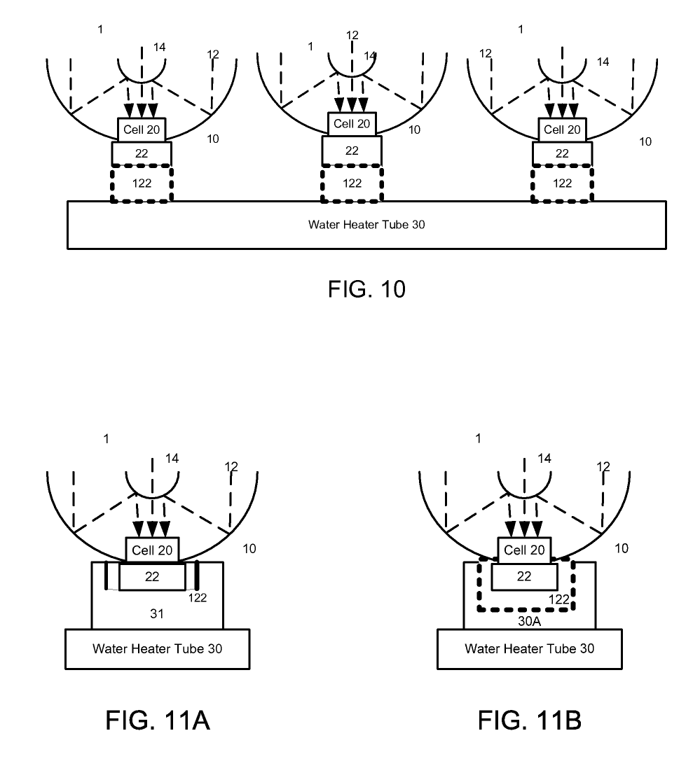

FIG. 10 shows another embodiment that is similar to FIG. 1, but adds one or more additional energy recovery devices 122 below the head spreader 22. The energy devices 122 can also be directly coupled to the solar cell 20. In the embodiment of FIG. 10, the first reflector 10 reflects sun light 12 to a second reflector 14. The second reflector 14 can be concave (Gregorian configuration) or convex (Cassegrain configuration). The second reflector 14 is mounted to a front window (not shown) for protection from the elements. The position of the solar cell 20 in FIG. 1 is for illustration purpose, and the solar cell is mounted below the first reflector 10 as is known to one skilled in the art. In general, the reflectors 10 and 14 focus the sun's energy into an optical rod, which guides the sunlight onto a solar cell 20 at the bottom of the rod. The high-efficiency cells are mounted to a heat spreader 22, which in turn is coupled to the energy recovery devices 122. The energy recovery devices 122 can further be thermally coupled to the water heater tube 30 that removes heat from the solar cell 20 and the heat spreader 22. High cell temperature not only reduces the cell performance but also reduces the reliability of the system, and so the water heater tube 30 removes the heat from the cells. The output of the heater tube 30 is heated water for subsequent use.

In one embodiment, the energy recovery device 122 can be a thermoelectric generator that converts heat into electrical energy. The conversion in a single junction involves generating low voltages and high currents. Thermoelectric voltage generation from the thermal gradient present across the conductor is inseparably connected to the generation of thermal gradient from applied electric current to the conductor. This conversion of heat into electrical energy for power generation or heat pumping is based on the Seebeck and Peltier effects. One embodiment operates on the Seebeck effect, which is the production of an electrical potential occurring when two different conducting materials are joined to form a closed circuit with junctions at different temperatures. As discussed in Application Serial No. 20020046762, the content of which is incorporated by reference, the Peltier effect relates to the absorption of heat occurring when an electric current passes through a junction of two different conductors. The third thermoelectric principle, the Thomson effect, is the reversible evolution of heat that occurs when an electric current passes through a homogeneous conductor having a temperature gradient about its length. The Seebeck effect is the phenomenon directly related to thermoelectric generation. According to the Seebeck effect, thermoelectric generation occurs in a circuit containing at least two dissimilar materials having one junction at a first temperature and a second junction at a second different temperature. The dissimilar materials giving rise to thermoelectric generation in accordance with the Seebeck effect are generally n-type and p-type semiconductors. Thermoelectricity between two different metals is then captured. With the Peltier heat recovery device, a significant portions of energy lost as waste heat could be recovered as useful electricity.

FIG. 10 shows a Seebeck/Peltier cell in the Seebeck mode with the side facing the solar cell being hot and one side facing the water heater tube 30 cold. FIGS. 11A-11B show two embodiments of cylindrical Seebeck/Peltier cells 122 connected in the Seebeck mode. In these embodiments, the cell 122 is a cylindrical tube that is positioned between the heat spreader 22 and the cooling tube 30. The hot electrode of the cylindrical cell 122 generates electric current of positive polarity and the cold electrode of the cylindrical cell 122 generates electric current of negative polarity. The material can be those discussed in US Application Serial No. 20030057512 where the thermoelectric generator or Peltier arrangement has a thermoelectrically active semiconductor material constituted by a plurality of metals or metal oxides the thermoelectrically active material is selected from a p- or n-doped semiconductor material constituted by a ternary compound, the content of which is incorporated by reference.

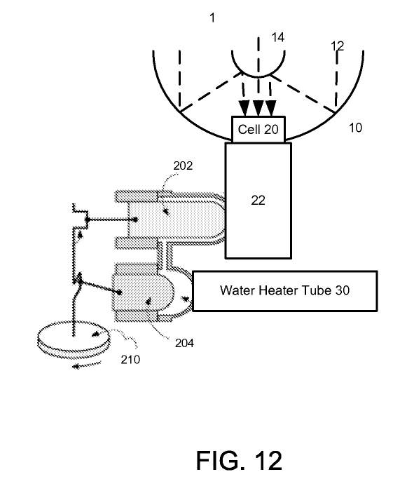

FIG. 12 shows a Stirling engine embodiment. In this embodiment, the heat spreader 22 drives a hot piston 202, while the water heater tube 30 removes heats from a cold chamber that contains a cold piston 204. The pistons 202-204 drive a shaft and turns wheel 210 to perform mechanical work or to turn an electrical dynamo to. The Stirling engine is a closed-cycle piston heat engine. The term “closed-cycle” means that the working gas is permanently contained within the cylinder, unlike the “open-cycle” internal combustion engine and some steam engines, which vent the working fluid to the atmosphere. The Stirling engine is traditionally classified as an external combustion engine, despite the fact that heat can be supplied by non-combusting sources such as solar energy. A Stirling engine operates through the use of an external heat source and an external heat sink, each maintained within a limited temperature range, and having a sufficiently large temperature difference between them. Since the Stirling engine is a closed cycle, it contains a fixed quantity of gas called a “working fluid”, most commonly air, hydrogen or helium. In normal operation, the engine is sealed and no gas enters or leaves the engine. No valves are required, unlike other types of piston engines. The Stirling engine, like most heat-engines, cycles through four main processes: cooling, compression, heating and expansion. This is accomplished by moving the gas back and forth between hot and cold heat exchangers. The hot heat exchanger is in thermal contact with an external heat source, e.g. a fuel burner, and the cold heat exchanger being in thermal contact with an external heat sink, e.g. air fins. A change in gas temperature will cause a corresponding change in gas pressure, while the motion of the piston causes the gas to be alternately expanded and compressed. The gas follows the behavior described by the gas laws which describe how a gas's pressure, temperature and volume are related. When the gas is heated, because it is in a sealed chamber, the pressure rises and this then acts on the power piston to produce a power stroke. When the gas is cooled the pressure drops and this means that less work needs to be done by the piston to compress the gas on the return stroke, thus yielding a net power output. When one side of the piston is open to the atmosphere, the operation of the cold cycle is slightly different. As the sealed volume of working gas comes in contact with the hot side, it expands, doing work on both the piston and on the atmosphere. When the working gas contacts the cold side, the atmosphere does work on the gas and “compresses” it. Atmospheric pressure, which is greater than the cooled working gas, pushes on the piston. In sum, the Stirling engine uses the potential energy difference between its hot end and cold end to establish a cycle of a fixed amount of gas expanding and contracting within the engine, thus converting a temperature difference across the machine into mechanical power. The greater the temperature difference between the hot and cold sources, the greater the power produced, and thus, the lower the efficiency required for the engine to run.

The output from the solar cells and the additional power source such as the Peltier cells or the Stirling engines are connected in series and the resulting output is boosted. Input voltage boosting is required so that the battery can be charged. To illustrate, if the solar cells generate only 20V of electricity, it is not possible to charge a 24V battery. A charger converts and boosts the voltage to more than 24V so that the charging of a 24V battery can begin. In one embodiment, the boosting of the voltage level is achieved using a step-up transformer. The voltage step-up by the transformer requires a relatively significant amount of energy to operate the charger. Hence, in another embodiment, a pulse-width-modulator (PWM) is used to boost the voltage.

The circuit is tailored for each battery technology in the battery, including nickel cadmium (Ni—CD) batteries, lithium ion batteries, lead acid batteries, among others. For example Ni—CD batteries need to be discharged before charging occurs.

In one embodiment, a solar tree having leaves on branches carrying leaf current collecting busses to a trunk bus in trunk. There may be several solar trees supplying their electrical energy to an underground line leading to building. In yet another embodiment, artificial grasses with solar cells embedded in grass blades receive concentrated sun rays from a concentrator. The ground where the solar grasses have current collecting busses connects to a trunk bus.

It will be apparent to those skilled in the art that various modifications and variation can be made in the present invention without departing from the spirit or scope of the invention. Thus, it is intended that the present invention covers the modifications and variations of this invention provided they come within the scope of the appended claims and their equivalents.

What is claimed is:

1. An energy device, comprising:
a. a solar concentrator that concentrates at least 20 suns on a predetermined spot;
b. a solar cell positioned on the predetermined spot to receive concentrated solar energy from the solar concentrator; and
c. a water heater pipe thermally coupled to the solar cell to remove heat from the solar cell.

2. The device of claim 1, wherein the solar concentrator heats the water heater pipe.

3. The device of claim 1, wherein the solar concentrator comprises one of: a mirror, a lens, a mirror-lens combination.

4. The device of claim 1, comprising an inverter to generate AC power to supply to an electricity grid and a water pump to distribute heated water to a building.

5. The device of claim 1, wherein the solar cell comprises one of: a quadruple junction solar cell, a quintuple junction solar cell.

6. The device of claim 5, wherein the AC voltage booster is one of: a step-up transformer, a pulse-width-modulation (PWM) voltage booster.

7. The device of claim 1, wherein the solar concentrator comprises a first curved reflector adapted to reflect light to a second curved reflector and wherein the second curved reflector concentrates sun light on the solar cell.

8. The device of claim 1, further comprising in one or more capacitors for storing a stepped-up voltage before applying the stepped-up voltage to a battery.

9. The device of claim 1, further comprising a frequency shifter to change a frequency of the AC voltage to avoid radio frequency interference.

10. The device of claim 1, further comprising a DC regulator coupled between the voltage booster and the battery.

11. A method for providing renewable energy, comprising:
a. concentrating sun light onto a photovoltaic (PV) cell;
b. receiving a direct current (DC) input voltage from the cell;
c. converting the direct current input voltage into an alternating current (AC) voltage;
d. stepping-up the AC input voltage; and
e. applying the stepped-up voltage to an energy storage device.

12. The method of claim 11, further comprising stepping-up the input voltage using pulse-width-modulation (PWM).

13. The method of claim 11, further comprising generating AC power from the battery.

14. The method of claim 11, comprising cooling the PV cell by heating up a water heater pipe.

15. The method of claim 11, comprising storing the stepped-up voltage in one or more capacitors before applying the stepped-up voltage to the battery.

16. The method of claim 11, comprising providing a second focal position for infrared wavelength and position an infrared solar cell at the second focal position.

17. The method of claim 11, comprising position the solar cell at first and second positions, wherein the second position is vertically offset from the first position.

18. The method of claim 11, comprising providing first and second mirrors positioned in a Cassegrain configuration.

19. The method of claim 11, comprising providing Fresnel lens to concentrate sun light onto the PV cell.

20. The method of claim 19, comprising providing a second lens between the Fresnel lens and the PV cell.
